(19) United States
(12) Patent Application Publication
(10) Pub. No.: US 2004/0227858 A1
(43) Pub. Date: Nov. 18, 2004

(54) [A/D CONVERSION PHASE ADJUSTING METHOD]

(76) Inventor: Jung-Yi Yang, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/605,216

(22) Filed: Sep. 16, 2003

(30) Foreign Application Priority Data
May 14, 2003 (TW) 92113043

(51) Int. Cl. H03M 1/12

(52) U.S. Cl. 348/572; 341/155

(57) ABSTRACT

One preferred embodiment of the present invention provides a phase adjusting method of an A/D video signal conversion. A plurality of phase references is applied to convert a number of analog video frames to a number of digital video frames. For each phase reference, an absolute display difference is obtained by adding up absolute differences between corresponding pixels that are at positions in the digital video frames. A target phase reference that produces a smallest absolute display difference is applied to convert a follow-up analog video frame, and a stable high quality digital display is obtained.

### CROSS REFERENCE TO RELATED APPLICATIONS

This application claims the priority benefit of Taiwan application serial no. 92113043, filed May 14, 2003.

### BACKGROUND OF INVENTION

1. Field of the Invention

The present invention pertains to a phase adjusting method of an analog-to-digital (A/D) video signal conversion in general, and more particularly to an optimized phase detecting method based on a plurality of video frames to adjust an A/D video signal conversion.

2. Description of the Related Art

In these modern times, as a use of a computer video system getting popular, how to display data precisely on a display device becomes an important issue for the industry. Currently, according to an input video signal, display devices can be grouped into two categories; one receiving an analog video signal is an analog-input video display device, and the other receiving a digital video signal is a digital-input video display device. Due to a cost issue and a relatively limited application support, the digital-input video display device is not yet as popular as the analog-in-put video display device in most circumstances. Therefore, the analog-input video display device is most commonly used in a computer video system.

According to a displaying image method, the analog-input video display device can be further grouped into two categories; one display device uses an analog-output display method, and the other display device uses a digital-out-put display method. For improving an image color resolution ability, more and more display devices use the digital-output display method instead of using the analogoutput display method. However, to an analog-input and digital-output display device, internally an A/D converter must be used to convert an input analog video signal to an output digital video signal to be able to be displayed on the display device.

Further, during an A/D conversion of a video signal, a choice of a display phase is critical to display quality of the analog-input and digital-output display device. Based on a single video frame, a current A/D display technology calculates a phase characteristic function; and based on the phase characteristic function, a phase for an A/D conversion is obtained. Surely, to calculate the phase characteristic function based on a single video frame is a way to obtain a phase required in an A/D video signal conversion, but there is no prove to indicate that the phase characteristic function is a better way to obtain a phase in A/D video signal conversion. In other words, in the current A/D video display technology, a better way to choose a phase during an A/D video signal conversion is still not yet defined.

### SUMMARY OF INVENTION

Accordingly, one preferred embodiment of the present invention provides a phase adjusting method of an A/D video signal conversion that effectively chooses a better phase for the A/D video signal conversion.

The preferred embodiment of the present invention also provides a phase adjusting method of an A/D video signal conversion that a phase in A/D video signal conversion is determined according to a relationship among adjacent video frames.

The preferred embodiment of the present invention also provides a phase adjusting method of an A/D video signal conversion that provides a stable display quality to a static image display.

The preferred embodiment of the present invention provides a phase adjusting method for an A/D video signal conversion. The phase adjusting method first collects a set of phases. Then, each phase in the set is applied to convert a plurality of analog video frames to corresponding digital frames. Next, a number of differences between a plurality of predetermined corresponding pixels in two digital frames are calculated, and absolute values of the differences are added up to obtain a sum of an absolute display difference. After all the phases in the set are applied to analog video frames, and after obtaining all absolute display differences of the phases in the set, a phase that provides a smallest absolute display difference is chosen to convert a following analog video frames to their corresponding digital frames.

In a preferred embodiment of the present invention, pixels at a center and four corners of a frame are chosen to calculate an absolute display difference between digital frames. Moreover, instead of calculating the smallest absolute display difference from the set of phases, a moving average calculation method can be also applied to the set of phases and video frames to obtain a phase that causes a smallest moving average. As a result, the phase producing the smallest moving average is chosen to be a base to convert an analog video signal to a digital video signal.

The preferred embodiment of the present invention further provides a phase adjusting method for an A/D video signal conversion where a phase reference is preset firstly. Then, the phase reference is applied to convert a first analog video frame to a first digital video frame, and a second analog video frame to a second digital video frame. Next, the phase adjusting method chooses a plurality of pixels from the first digital frame and, at same positions, chooses a plurality of pixels from the second digital frame. An absolute display difference is obtained by adding up an absolute difference between two pixels at a frame position of the two digital frames all over the positions where the pixels are chosen. Next, the phase reference is changed to another value, and the same procedure described above is applied, as a consequence, a new absolute display difference is obtained accordingly. After several trials, a phase reference producing a smallest absolute display difference is chosen to perform a following A/D video signal conversion.

The embodiment of the present invention uses relationship between two digital frames to obtain a phase characteristic function and a curve of digital frames. Further, with the phase characteristic function and the curve, a phase causing a smallest difference between two digital frames is obtained. Accordingly, a preferred embodiment of the present invention provides a static dominant display application, such as a computer or a projector application, to have a stable display quality.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. The drawings are as follows.

FIG. 1 demonstrates an image processing apparatus in a block diagram that is commonly used in a display apparatus with analog video input.

FIG. 2 depicts the steps of the phase adjusting method of a preferred embodiment of the present invention in a flow-chart diagram.

FIG. 3 depicts that pixels are chosen from two digital frames in the preferred embodiment of the present invention.

FIG. 4A and FIG. 4B depicts an absolute display difference curve that is produced according to the preferred embodiment of the present invention.

FIG. 5 depicts the steps of the phase adjusting method of another preferred embodiment of the present invention in a flow-chart diagram.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

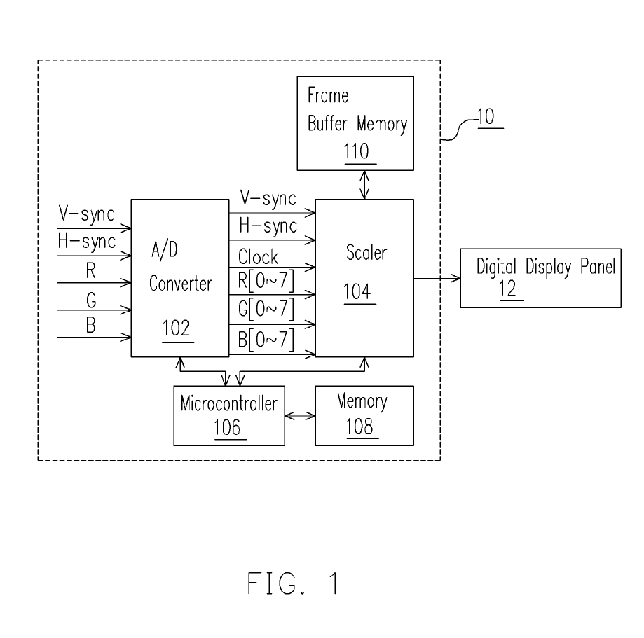

For allowing those skilled in the art to understand the invention easily, before introducing a phase adjusting method of the embodiment of the invention, a hardware structure for the method is first introduced as follows. Referring to FIG. 1, a commonly used image processing apparatus with analog video input is depicted in a block diagram. In the figure, an image processing apparatus10 receives an analog video signal including a vertical synchronization (V-sync) signal, a horizontal synchronization (H-sync) signal, a red (R) signal, a green (G) signal, and a blue (B) signal from a host (not shown in figures). Wherein the analog video signal is converted to a digital video signal prior to display on a digital display panel 12.

The image processing apparatus10 comprises an A/D converter102, a scaler104, a microcontroller 106, a memory 108, and a frame buffer memory110. An analog video signal received via the image processing apparatus10 is first converted to a digital video signal by the A/D converter 102 before sending to the scaler104. The scaler104 temporarily stores the digital video signal to the frame buffer memory110, and according to a preset value in the image processing apparatus enlarges or shrinks a digital image contained in the digital video signal to fit on the digital display device 12. The micro-controller 106 and the memory 108 are used to execute and store a program and data doing the tasks described above.

A phase setting in the A/D converter102 is critical to obtain a clear and stable image display. In other words, an improper phase setting causes a fuzzy image display, whereas a better phase setting brings a clear and sharp image display on the display device. The preferred embodiment of the present invention provides a method to obtain a better phase setting to optimize an image display.

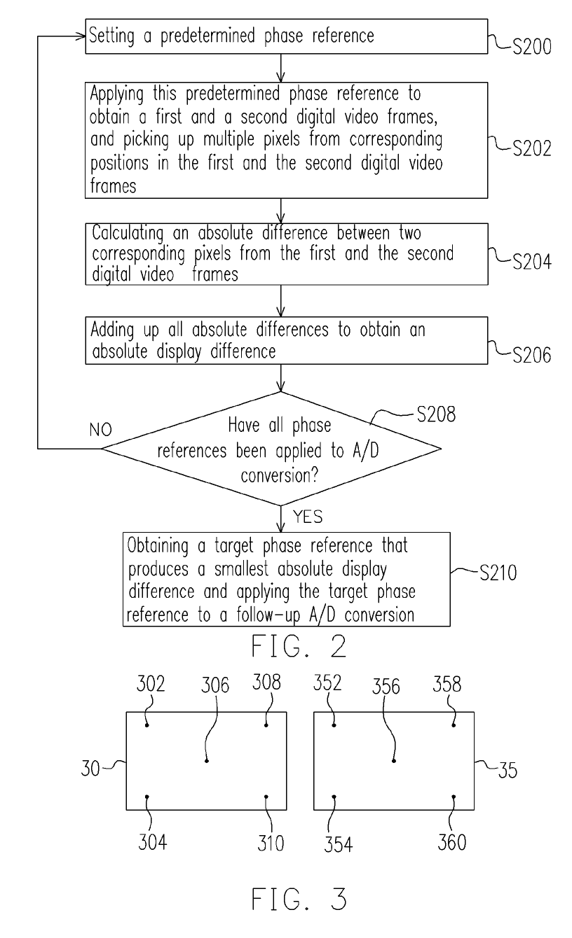

Referring to FIG. 2, a procedure of performing a preferred embodiment of the present invention is demonstrated in a flow-chart diagram. In the preferred embodiment of the present invention, a preset phase reference is first determined in step S200. Then, the preset phase reference is applied to convert a first analog video frame and a second analog video frame to a first digital video frame and a second digital video frame. In step S202, a plurality of pixels are picked up from the first digital video frame, and at the same positions, the corresponding pixels are picking from the second digital video frame. As depicted in FIG. 3, and as an example, digital video frames 30, 35 represents the first digital video frame and the second digital frame, and are converted from a pair of analog video frames based on the same phase reference. It is noted that a pixel 302 in the first video frame 30 and a pixel 352 in the second video frame 35 are at a same frame position. Similarly, pixels 304, 306, 308, 310 in the first video frame 30 and pixels 354, 356, 358, 360 in the second video frame 35 are at same frame positions respectively. It is also noted that in the example, positions of four corners and a center of a frame are chosen for the pixels to pick up from. However, the number of pixels and the positions where the pixels are chosen from are flexible and are based on a need of an exercise of the preferred embodiment of the present invention.

Next, in step S204, an absolute difference between two pixels from a position in the first and the second digital video frames is calculated. For example, in FIG. 3, an absolute difference between pixels from a position is an absolute difference of RGB display values of pixels 302, 352. In step S206, a summation of all absolute difference between pixels from all positions is calculated to obtain an absolute display difference between two digital video frames. For example, in FIG. 3, an absolute display difference between two digital video frames is obtained by adding up absolute differences between display values of pixels 302, 352, pixels 304, 354, pixels 306, 356, pixels 308, 358, and pixels 310, 360.

Step S208 provides a testing mechanism to test out if all target phase references are applied to convert analog video frames. If the answer is negative, the method picks up a not yet applied phase reference and jumps to step S200, and steps S200 to S206 are executed accordingly. After all the target phase references are applied to convert analog video frames, and all the absolute display differences are obtained, a smallest absolute display difference is picked up. In step S210, a phase reference resulting in the smallest absolute display difference is applied to a following A/D converting task.

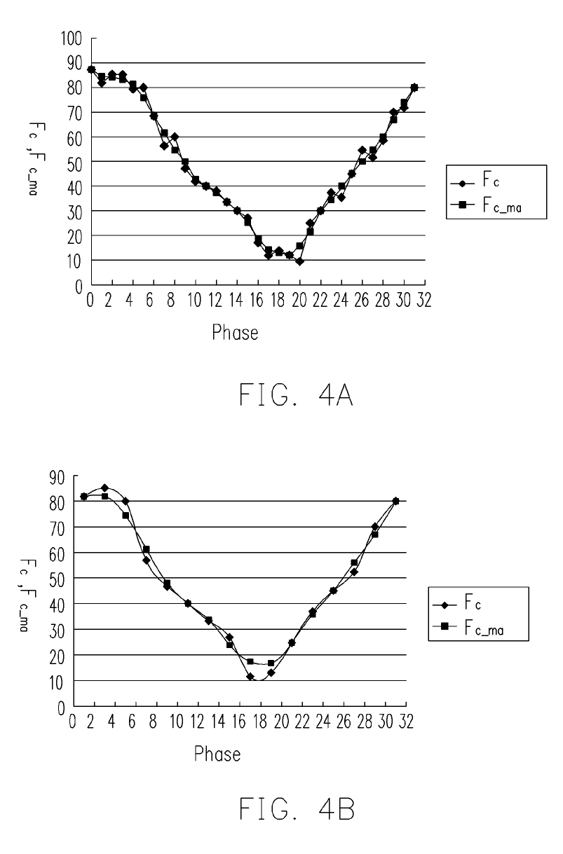

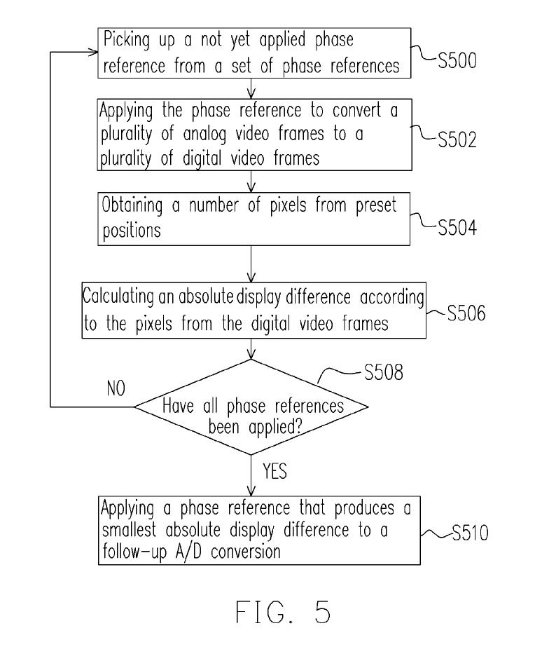

In a preferred embodiment of the present invention, in step S210, a moving average method is applied to the absolute display differences to obtain a moving average curve. Referring to FIG. 4A, thirty-two phase references (0 to 31) are applied to a sequence of analog video frames to obtain thirty-two absolute display differences, and the absolute display differences are depicted in FIG. 4A.

In FIG. 4A, the rhombus points in curve F_{c} represent the absolute display differences, and after apply the moving average method to the absolute display differences, the curve F_{c}_{_{—}}ₘₐ comprises square points is obtained. Referring to FIG. 4A herein. In the curve F_{c}, the twentieth rhombus point is the lowest point in the curve, thus its corresponding phase reference is chosen to perform an A/D conversion. Whereas in the curve F_{c}_{_{—}}ₘₐ, the nineteenth square point is the lowest pint in the curve, thus its corresponding phase reference is chosen to perform an A/D conversion. It is clear that the results from the two curves are similar and display qualities of these two-phase references are almost identical. To those skilled in the art, based on different circumstances, results from the moving average method or directly from the absolute display differences can be used to meet their needs.

To save time on picking up a better phase reference, in a preferred embodiment of the present invention, a better phase reference is picked up from a reduced set of phase references. In FIG. 4B, a phase reference is only picked up from an odd number position of the set of the phase references, so that a half time is saved comparing with the results from FIG. 4A. Clearly, since the number of the phase references is reduced, accuracy in picking up the smallest absolute display difference is reduced as well. For example, in FIG. 4B, by following curve F_{c}, the smallest absolute display difference is at the seventeenth phase reference; however, by following curve F_{c}_{_{—}}ₘₐ, the smallest absolute display difference is at the nineteenth temptempphase reference. In practice, a user can pick up either one to meet the user”s need. Basically, a minor difference between two phase references results in a minor difference of display resolutions.

Moreover, before a video frame is obtained, writing a video frame to a frame buffer, for instance the frame buffer memory110 in FIG. 1, causes a delay, and an A/D conversion also takes time. To save time in obtaining a better phase reference, consecutive video frames are used to calculate an absolute display difference, and a number of video frames are reduced for a phase reference. Referring to FIG. 5, steps of the phase adjusting method of a preferred embodiment of the present invention are demonstrated in a flow-chart diagram. In FIG. 5, the method first picks up a phase reference from a set of phase references in step S500. In step S502, the phase reference is applied to convert a plurality of analog video frames to a plurality of digital video frames. Then, at same frame positions, a number of corresponding pixels are chosen from each of the digital video frames in step S504. An absolute display difference is calculated in step S506. Next, in step S508, a test procedure is taken to determine if all the phase references in the set of phase references have been applied to convert analog video frames. Steps S500 to S506 are repeated if a phase reference is found not yet applied to convert an analog video frame. If all the phase references in the set are applied to convert analog video frames, in step S510, a phase reference producing a smallest absolute display difference is used to convert a following analog video frame.

Similar to above description, the moving average method can be applied to the absolute display differences found in S510 so as to obtain a curve and thus a phase reference that causes a lowest point in the curve.

As a summary to the above description, the preferred embodiment of the present invention provides a phase adjusting method in which a number of phase references are applied to convert a number of analog video frames. After the conversion, absolute display differences are calculated; thereby, a phase reference produces a smallest absolute display difference is picked up to convert a following analog video frame. By applying the preferred embodiment of the present invention to a computer image display or a projector image display, a clear and highresolution display is easily obtained.

It will be apparent to those skilled in the art that various modifications and variations can be made to the structure or to the methods of the preferred embodiment of the present invention without departing from the scope or spirit of the invention. In view of the foregoing, it is intended that the present invention cover modifications and variations of this invention provided they fall within the scope of the following claims and their equivalents.

1. A phase adjusting method of an analog-to-digital (A/D) video signal conversion, which comprises setting a phase reference;
applying the phase reference to convert a first analog video frame to a first digital video frame and collecting a first set of pixel value of a plurality of predetermined positions from the first digital video frame;
applying the phase reference to convert a second analog video frame to a second digital video frame and collecting a second set of pixel value of said plurality of predetermined positions from the second digital video frame;
calculating an absolute display difference by adding up absolute differences between corresponding pixels in the first set and the second set of pixel value;
obtaining another phase reference and doing the above procedures over again to obtain another absolute display difference, choosing a target phase reference that produces a smallest absolute display reference; and
applying said target phase reference to convert a following analog video frame.

2. The phase adjusting method of claim 1, wherein said plurality of predetermined positions are at four corners and a center of the digital video frame.

3. The phase adjusting method of claim 1, wherein the first video frame and the second video frame are consecutive frames.

4. The phase adjusting method of claim 1, wherein before obtaining the first digital video frame and the second digital video frame, a delay occurs for storing the first digital video frame and the second digital video frame to a frame buffer memory.

5. The phase adjusting method of claim 1, wherein a moving average calculating method is applied to the absolute display differences to obtain a plurality of moving averages.

6. The phase adjusting method of claim 5, wherein a best phase reference for the A/D conversion produces a smallest moving average.

7. A phase adjusting method of an analog-to-digital (A/D) video signal conversion, which comprises obtaining a plurality of digital video frames of the A/D conversion by setting a phase reference that is a member of a set of phase references;
calculating an absolute display difference by adding up absolute differences between pixel value for corresponding pixel positions in the plurality of digital video frames;
picking up another phase reference from the set of phase references and repeating the above procedures; and
choosing a target phase reference that produces a smallest absolute display difference to convert a following analog video frame.

8. The phase adjusting method of claim 7, wherein said corresponding pixel positions are at four corners and a center of the frames.

9. The phase adjusting method of claim 7, wherein the plurality of digital video frames are consecutive frames.

10. The phase adjusting method of claim 7, wherein before obtaining the plurality of digital video frames, a delay occurs for storing the plurality of digital video frames to a frame buffer memory.

11. The phase adjusting method of claim 7, wherein a moving average calculating method is applied to the absolute display differences to obtain a plurality of moving averages.

12. The phase adjusting method of claim 11, wherein a best phase reference for the A/D conversion produces a smallest moving average, and the best phase reference is used in a follow-up A/D conversion.
